(19) United States
(12) Patent Application Publication
(10) Pub. No.: US 2026/0101564 A1
(43) Pub. Date: Apr. 9, 2026

(54) GROUP III-N DEVICE WITH SILICIDED SUBSTRATE CONTACT

(71) Applicant: TEXAS INSTRUMENTS INCORPORATED, Dallas, TX (US)

(72) Inventors: Dong Seup Lee, Allen, TX (US); Hiroshi Yamasaki, Aizuwakamatsu-shi (JP); Masahiko Higashi, Aizuwakamatsu-shi (JP); Takayuki Enda, Aizuwakamatsu-shi (JP)

(21) Appl. No.: 18/908,236

(22) Filed: Oct. 7, 2024

(51) Int. Cl. H01L 29/49; H01L 21/285; H01L 27/085; H01L 29/10; H01L 29/20; H01L 29/423; H01L 29/66; H01L 29/778

(52) U.S. Cl. CPC H10D 64/668; H10D 62/378; H10D 64/0125; H10D 64/27; H10D 30/015; H10D 30/47; H10D 62/8503; H10D 84/82

(57) ABSTRACT

Semiconductor devices including a silicided substrate contact are described. In one example, a semiconductor device comprises a semiconductor substrate and a heterojunction structure over the semiconductor substrate, where the heterojunction structure includes a III-N buffer layer over the semiconductor substrate and a III-N barrier layer over the III-N buffer layer. A substrate contact extends through the heterojunction structure and to the semiconductor substrate, where the substrate contact includes a silicide layer contacting the semiconductor substrate.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprises a semiconductor substrate and a heterojunction structure over the semiconductor substrate, where the heterojunction structure includes a III-N buffer layer over the semiconductor substrate and a III-N barrier layer over the III-N buffer layer. A substrate contact extends through the heterojunction structure and to the semiconductor substrate, where the substrate contact includes a silicide layer contacting the semiconductor substrate.

In one example, a method of fabricating a III-N semiconductor device is disclosed. The method comprises forming a heterojunction structure over a semiconductor substrate, the heterojunction structure including a III-N buffer layer over the semiconductor substrate and a III-N barrier layer over the III-N buffer layer; forming a dielectric layer over the heterojunction structure; forming a trench through the dielectric layer and extending to the semiconductor substrate; lining the trench with a refractory metal layer; and annealing the refractory metal layer to form a silicided bottom in the trench. In some arrangements, the method may optionally include implanting the trench before forming the refractory metal layer.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1G depict cross-sectional views of a semiconductor device including one or more substrate contacts with respect to a GaN device at various stages of a process flow according to an example of the present disclosure; and

FIG. 2 is a flowchart of a method of fabricating a III-N semiconductor device according to some examples.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2 DEG) formed within the AlGaN/GaN hetero epitaxy structure that is used for device operation—e.g., forming a channel of the GaN device. The 2-dimensional electron gas (2 DEG) may be referred to as a 2 DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2 DEG beneath the gate stack at zero or negative gate bias. In some examples, the p-GaN layer may comprise a GaN layer doped with magnesium (Mg) or other p-type dopants. Applying a positive gate voltage, e.g., a threshold voltage, enhances the 2 DEG under the gate and turns the EMODE GaN device on to allow current flow between the source and the drain.

In some examples, a GaN device may be formed with one or more GaN layers over a suitable semiconductor substrate, e.g., including a silicon substrate, where a portion of the GaN layers may form a heterojunction structure over the semiconductor substrate. In this approach and for proper operation, one or more electrical contacts may be desirable from higher layers in the device to the silicon substrate. For example, such contact(s) may permit maintaining or applying a required bias in or to the silicon substrate, which may enable the GaN device(s) to handle higher currents. Further, in certain GaN power applications, topside substrate contacts may be needed, e.g., where flip-chip packaging is used. Reducing contact resistance, including substrate contact resistance, is generally desired in a device because the reduced substrate contact resistance may lower power losses in the device as well as the application system including the device. Moreover, reduced substrate contact resistance may enable the fabrication of smaller substrate contacts in a device, which may help reduce the overall device area, thus potentially leading to increased device integration and greater die yields (e.g., die per wafer or DPW). However, integrating substrate contacts to the silicon substrates while attaining desired circuit density has been challenging.

Examples of the present disclosure recognize the foregoing needs and attendant challenges and provide a solution for improving (e.g., reducing) substrate contact resistance in a semiconductor device including one or more GaN devices. In some arrangements, one or more substrate contacts may be formed in respective trenches extending through a heterojunction structure and into a semiconductor substrate underlying the heterojunction structure. Depending on implementation, a suitable refractory metal layer lining the trenches is silicided (e.g., by annealing the refractory metal layer in contact with a silicon substrate at an elevated temperature) before forming an entire contact metal stack in a metallization process. Accordingly, a bottom portion of the substrate contact comprising the refractory metal layer having direct contact with the silicon substrate material is silicided, resulting in an Ohmic contact having lower resistance. In some arrangements, the substrate contacts may be formed using a lower level metal layer of the metallization process. Some examples may therefore include the fabrication of substrate contact using metal stack structures having less pronounced vertical topographies, thus facilitating tighter definitions and smaller areas for substrate contact formation. Whereas the examples herein may provide various structures, materials and processes that may engender these and other beneficial effects, no particular result is a requirement unless explicitly recited in a particular claim.

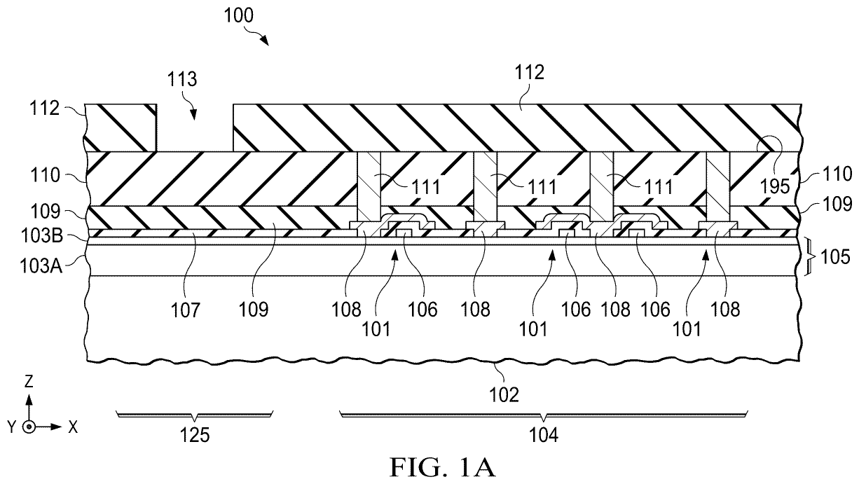

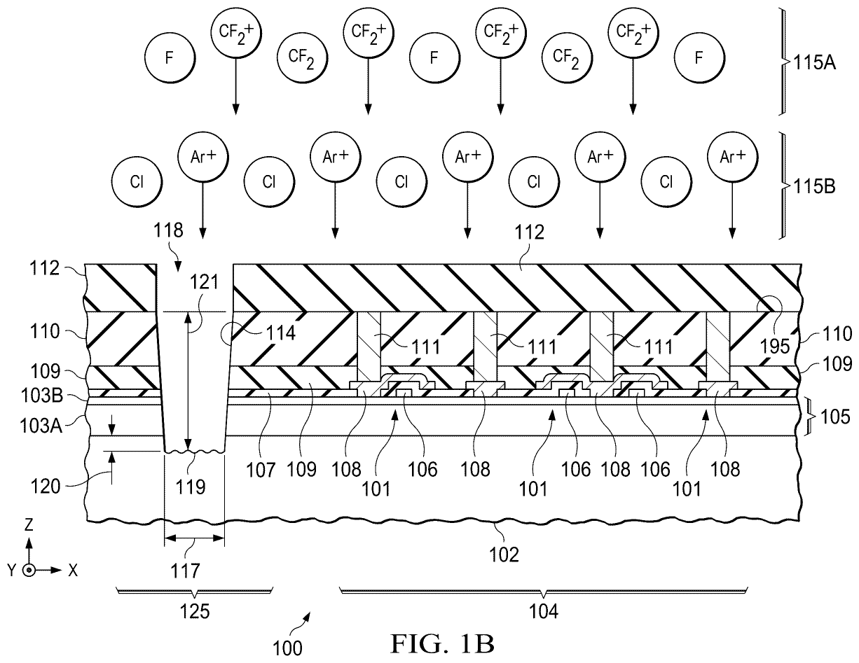

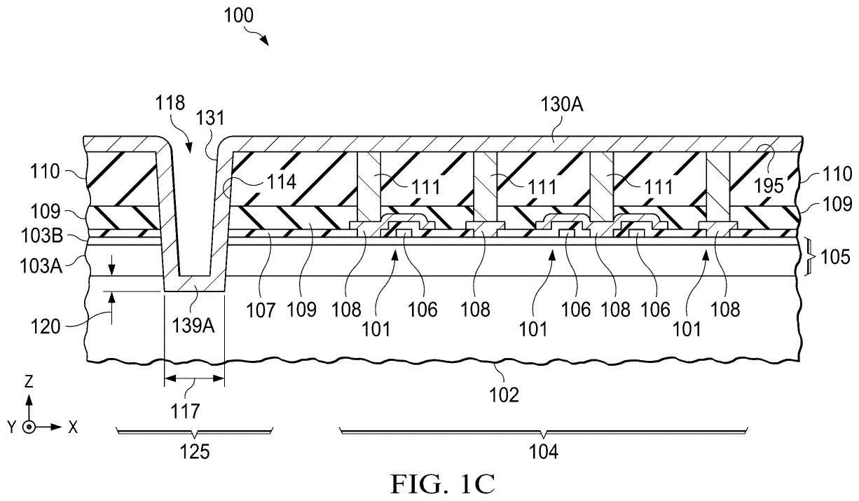

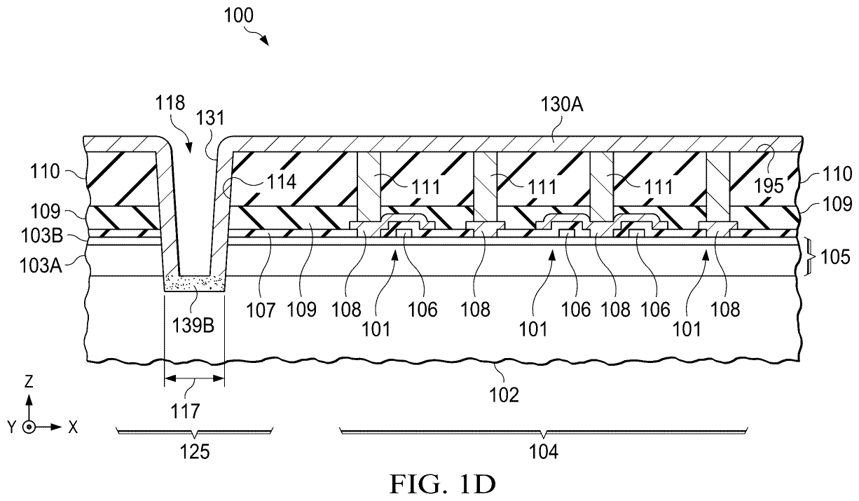

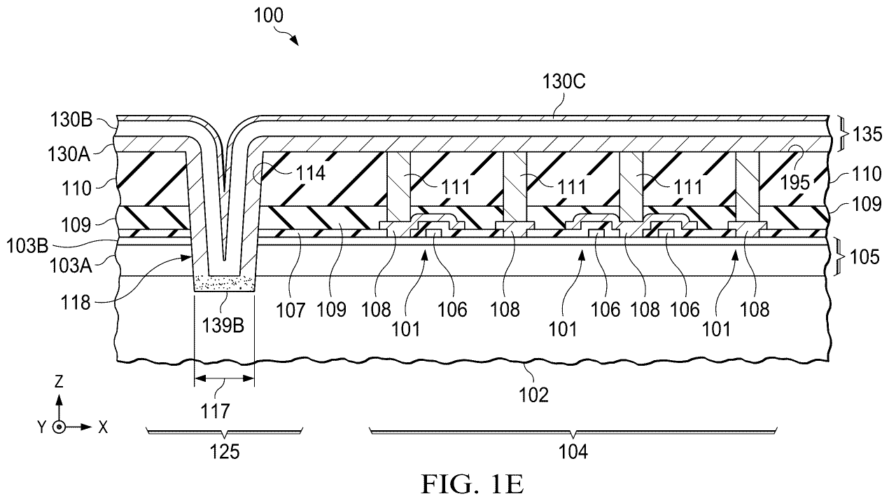

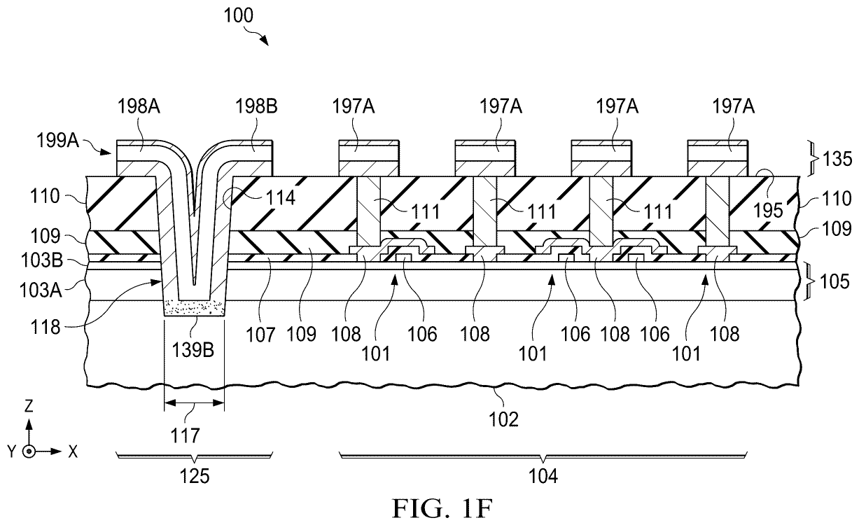

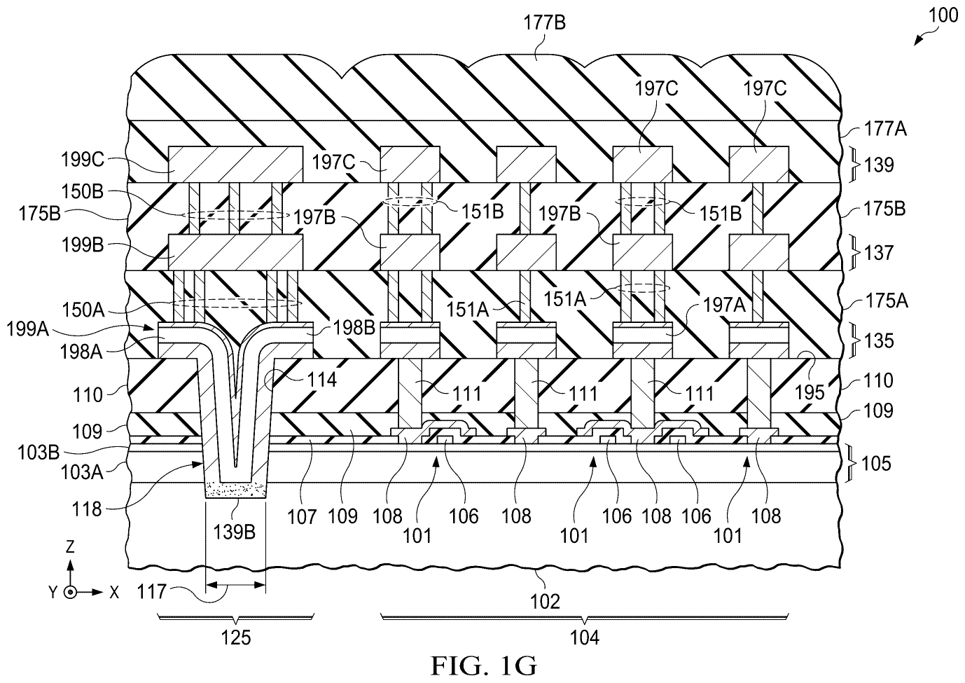

Referring to the drawings, FIGS. 1A-1G depict cross-sectional views of a semiconductor device 100 including one or more substrate contacts with respect to a GaN device at various stages of a process flow according to some examples of the present disclosure. FIG. 1A depicts a cross-sectional view of the semiconductor device 100 after completion of forming one or more GaN devices, e.g., GaN transistors 101, in a device region 104 of a semiconductor substrate 102, where each GaN transistor 101 may have source and drain electrodes 108 and a gate structure 106. A substrate contact region 125 may be provided in the semiconductor substrate 102 for facilitating the formation of one or more substrate contacts using a metal layer of appropriate level of a multilevel metallization flow as will be set forth in detail further below. In some arrangements, the semiconductor substrate 102 may be provided as part of a silicon wafer, for example, that may comprise p-type semiconductor material (e.g., including boron) or n-type semiconductor material (e.g., including arsenic or phosphorus). Depending on integration and implementation, the semiconductor substrate 102 may represent a portion of the bulk wafer or a region (e.g., a well and/or buried layer and/or epitaxial layer). Additionally and/or alternatively, the semiconductor substrate 102 may be provided as part of a silicon-on-sapphire wafer, a silicon carbide wafer, and/or as a semiconductor substrate including a core configured for matching coefficient of thermal expansion (CTE), and/or the like.

A buffer layer 103A comprising one or more layers of III-N semiconductor material is formed on the semiconductor substrate 102. In some examples where the semiconductor substrate 102 is implemented as a silicon wafer or a sapphire wafer, the buffer layer 103A may include a nucleation layer having a stoichiometry that includes aluminum to match a lattice constant of the semiconductor substrate 102. In some examples, the buffer layer 103A may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 103A, are not specifically shown in the Figures of the present disclosure.

Depending on implementation, the buffer layer 103A may have a thickness of about 1 micron (μm) to several microns, e.g., 3.5 μm to 7.0 μm, which may be formed by a suitable epitaxial process, e.g., a metal organic vapor phase epitaxy (MOVPE) process (also known as organometallic vapor phase epitaxy (OMVPE) or metalorganic chemical vapor deposition (MOCVD)), where several sequential steps may be performed to form the various layers and/or sublayers. In some arrangements, an example buffer layer 103A may comprise a stack of multiple layers/sublayers of suitable materials and compositions (e.g., GaN, AlGaN, etc.) as noted above, where the layers/sublayers may have variable thicknesses depending on the technology and device application. In some arrangements, the buffer layer 103A may include AlGaN-based transition layers, epitaxial layers with strain-layer superlattice (SLS) structures, and the like.

A channel layer (not specifically shown in FIGS. 1A-1G) may be provided as part of the buffer layer 103A—e.g., a top portion of the buffer layer 103A proximate to a barrier layer 103B. Whereas a channel layer may primarily include GaN material, there may be optional trace amounts of other group III elements, such as aluminum or indium, in some implementations.

A barrier layer 103B comprising III-N semiconductor material is formed over the buffer layer 103A in a suitable epitaxy process. In an example arrangement, the barrier layer 103B may have a thickness ranging from about 1 nanometer (nm) to about 60 nm, and may include aluminum and nitrogen. In some versions of this example, the barrier layer 103B may include gallium at a lower atomic percent than aluminum. In some versions, the barrier layer 103B may also include indium. In some examples, the barrier layer 103B includes an AlGaN layer.

The barrier layer 103B over buffer layer 103A is operable as part of a heterojunction structure 105 for causing the formation of a 2 DEG (not shown in FIGS. 1A-1G) proximate to an interface between the barrier layer 103B and the buffer layer 103A. In some examples, the stoichiometry and thickness of the barrier layer 103B may be configured to provide a suitable free charge carrier density (e.g., 3×10¹² cm⁻² to 2×10¹³ cm⁻²) of the 2 DEG for facilitating the device operation.

In some arrangements, other types of GaN layers, e.g., p-doped GaN or p-GaN, AlGaN cap layers, etc., may be formed over the heterojunction structure 105 for purposes of effectuating EMODE functionality. Whereas in a normally on mode GaN FET device (i.e., a DMODE device), the 2 DEG extends from a source region to a drain region of the device without any discontinuity, in an EMODE device (i.e., a normally off mode device), the 2 DEG is absent or reduced in a gate region (e.g., under the gate structure 106) until the device is turned on. Although FIGS. 1A-1G do not specifically illustrate a p-GaN layer, examples of substrate contact formation will be set forth below without being limited to either EMODE or DMODE functionality of the GaN devices 101 for purposes of the present disclosure.

Various constituent layers of the heterojunction structure 105 (as well as a p-GaN stack where provided) may be formed by a sequence of epitaxial processes as noted previously. In an example implementation, the epitaxial processes may use a nitrogen-containing gas reagent/source such as ammonia (NH₃), an aluminum-containing gas reagent/source such as trimethylaluminum (TMA), and a gallium-containing gas reagent/source such as trimethylgallium (TMG) or triethylgallium (TEG), which may be provided using a carrier gas (e.g., N₂ or H₂) for sequentially growing the various layers/sublayers. For purposes of the present disclosure, the combination of various layers and sublayers of the heterojunction structure 105 (as well as a p-GaN stack and optional AlGaN cap layers where provided) may be collectively referred to as a III-N epi stack, which may extend over the semiconductor substrate 102 including the substrate contact region 125. Although not specifically shown in FIGS. 1A-1G, the III-N epi stack may also extend to a guard ring (GR) region that may surround the device region 104 and the substrate contact region 125 in some additional and/or alternative examples. Further, the III-N epi stack may also extend to a scribe lane (not shown in FIGS. 1A-1G) associated with the semiconductor device 100 in some additional and/or alternative examples. Accordingly, some examples of substrate contact fabrication set forth herein may be integrated with the formation of GR structures and/or scribe lane structures in some additional and/or alternative arrangements.

After forming the heterojunction structure 105 (as well as a p-GaN stack and associated cap layers where provided), device electrodes (e.g., source/drain electrodes 108 and gate electrodes associated with the gate structures 106) may be formed where an example process flow may include the formation of one or more dielectric layers that may be patterned using appropriate mask and etch processes. In some arrangements, a gate structure including a gate electrode may be formed before forming the source/drain electrodes (e.g., in a gate first process flow) of a GaN device. In some arrangements, the source/drain electrodes may be formed before forming a gate electrode (e.g., in a gate last process flow). Accordingly, set forth below is a representative process flow for purposes of some examples herein without being limited to any particular sequential order of steps for fabricating device electrodes associated with the GaN devices 101.

In some arrangements, a dielectric layer 107 may be formed on the III-N stack extending over the device region 104 and the substrate contact region 125. In some arrangements, the dielectric layer 107 may comprise a silicon nitride (SiN) layer having a thickness of about 20 nm to 100 nm that may be deposited using a low pressure chemical vapor deposition (LPCVD) process. In some arrangements, the dielectric layer 107 may be operable as a surface passivation layer, which may also be referred to as a first pre-metal dielectric (PMD) layer. In some arrangements, source/drain electrodes 108 may be formed through the dielectric layer 107 to make electrical contact with source/drain regions of the GaN devices 101.

In some arrangements, electrodes associated with gate structures 106 may be formed in respective gate regions of the GaN devices 101 before or after the formation of the source/drain electrodes 108. A second dielectric layer 109, which may be referred to as a second PMD layer, may be formed over the first dielectric layer 107 and the source/drain electrodes 108, where the second dielectric layer 109 may have a thickness of about 0.5 μm to 5 μm. In an example, the second dielectric layer 109 may include silicon nitride (SiN) or silicon dioxide (SiO₂). Alternatively, the second dielectric layer 109 may include plural layers, for example, a first layer of SiN followed by a second layer of SiO₂. Depending on implementation, the second dielectric layer 109 (or its layers) may be formed by plasma enhanced chemical vapor deposition (PECVD) or by a high density plasma (HDP) deposition, e.g., in a low temperature process (e.g., at or below 300° C.).

In some arrangements, a third dielectric layer 110 is formed over the second dielectric layer 109. The third dielectric layer 110 may be referred to as a third PMD layer 110, and may include primarily SiO₂. The third dielectric layer 110 may be formed by a PECVD process or an HDP process. The third dielectric layer 110 may be sufficiently thick to provide dielectric isolation between source and drain potentials, and to reduce capacitive coupling, during operation of the semiconductor device 100. By way of example, the third dielectric layer 110 may have a thickness of about 1.0 μm to 5 μm.

In some arrangements, the second dielectric layer 109 and/or the third dielectric layer 110 may be optionally planarized, e.g., by a chemical mechanical polish (CMP) process and/or an etch-back process. Contacts 111 may be formed through the third dielectric layer 110 and the second dielectric layer 109 to make electrical connections to the source/drain electrodes 108. The contacts 111 may be formed by etching contact holes through the third dielectric layer 110 and the second dielectric layer 109 to expose portions of the source/drain electrodes 108. In some arrangements, the contacts 111 may include an adhesion liner of titanium (Ti) formed by a sputter process over the third dielectric layer 110, where the adhesion liner may extend into the contact holes and on the exposed portions of the source/drain electrodes 108. In some arrangements, the contacts 111 may include a barrier liner of titanium nitride (TiN) on the adhesion liner, and may include tungsten (W) plugs formed by an MOCVD process including reduction of tungsten hexafluoride (WF₆). Any excess or overburden of contact metallization over a top surface 195 of the third dielectric layer 110, e.g., comprising tungsten, barrier liner and adhesion liner materials, may be removed by a CMP process, an etchback process, or a combination of both.

To facilitate the formation of substrate contacts in the substrate contact region 125, a substrate via etch mask 112 is formed over the third dielectric layer 110 and the contacts 111 as shown in FIG. 1A. The substrate via etch mask 112, also referred to as a trench etch mask, may be patterned to expose the third dielectric layer 110 in one or more openings or apertures 113. The substrate via etch mask 112 may include photoresist, formed by a photolithographic process, and may include anti-reflection material such as an organic bottom anti-reflection coating (BARC) under the photoresist.

FIG. 1B depicts a stage for forming a trench 118 corresponding to the opening 113 in the substrate contact region 125 using a suitable trench etch process, where the trench 118 extends through a dielectric stack (e.g., comprising the third dielectric layer 110, the second dielectric layer 109 and the first dielectric layer 107) as well as the III-N stack (e.g., including the heterojunction structure 105) to expose the semiconductor substrate 102. In some arrangements, the trench 118 may extend into the semiconductor substrate 102 by a desired distance 120 (e.g., around 1.0 μm to 2.0 μm or less), which may be formed by a dry etch process having an over-etch in the semiconductor substrate 102. Accordingly, the trench 118 may have a depth 121 from the top surface 195 of the third dielectric layer 110 to a bottom 119, where the depth 121 may include the distance 120 into the semiconductor substrate 102. Further, the trench 118 may have sidewalls 114 that may be tapered in some arrangements, e.g., a vertical deviation of less than 5° to 10° relative to a surface normal of the bottom 119. In some additional and/or alternative arrangements, there may be no over-etch and the bottom 119 of the trench 118 may be disposed on a top surface of the semiconductor substrate 102, e.g., proximate to an interface between the semiconductor substrate 102 and the buffer layer 103A.

Depending on implementation, an example trench etch process may include one or more reactive ion etch (RIE) processes 115A, 115B as shown in FIG. 1B. In some arrangements, a first RIE process 115A may use one or more halogen etchant species, such as carbon tetrafluoride (CF₄) or ethane hexafluoride (C₂F₆). Suitable radio frequency (RF) power may be applied to the halogen etchant species to generate electrons, ions, such as CF₂⁺, and radicals, e.g., species having one or more unpaired electrons, such as atomic fluorine (F) and difluorocarbene (CF₂), as depicted in FIG. 1B. Other species of ions and/or radicals are within the scope of some versions of this example. In some arrangements, the first RIE process 115A may alternate between different halogen etchant species when transitioning between etching SiO₂ and etching SiN. In some arrangements, the first RIE process 115A may be end-pointed or may be a timed etch where the material from the various dielectric layers 110, 109, 107 is removed and the III-N stack material is exposed in a partially formed trench.

In some arrangements, inductively coupled plasma (ICP) may be used in a second RIE process 115B to remove the exposed III-N material and complete the formation of the trench 118. Depending on implementation, the second RIE process 115B may use a variety of chemical etchant species such as chlorine (Cl₂), silicon tetrachloride (SiCl₄), boron trichloride (BCl₃), or boron tribromide (BBr₃) and/or physical etchant species, such as argon (Ar), helium (He), oxygen (O₂), or silicon tetrafluoride (SiF₄). Additional details relating to forming contact trenches in a substrate contact region such as the substrate contact region 125 may be found in the following U.S. Patent Applications: (i) application Ser. No. 18/345,939, filed Jun. 30, 2023; and (ii) application Ser. No. 18/400,672, filed Dec. 29, 2023; each of which is incorporated by reference herein in its entirety for all purposes.

After forming the trench 118, the substrate via etch mask 112 is removed. In some arrangements, the substrate via etch mask 112 may be removed by a plasma process using oxygen radicals and ions, such as an ash process, followed by a wet clean process using an aqueous mixture of hydrogen peroxide (H₂O₂) and ammonium hydroxide (NH₄OH). Alternatively, the substrate via etch mask 112 may be removed by a wet strip process using n-methyl pyrrolidone (NMP) or an aqueous mixture of sulfuric acid (H₂SO₄) and H₂O₂, followed by an ash process, which may then be followed by an additional wet clean process.

Because example substrate contact formation processes set forth herein may be advantageously configured to provide lower contact resistance due to silicidation, substrate contact trenches such as the trench 118 may be formed with smaller sizes in an example implementation. In some versions of this example, the bottom 119 of the substrate contact trench 118 may have a width 117 (e.g., along a horizontal X-axis perpendicular to the depth 121) that may range from about ≤1 micron (μm) to about 20 μm. In some additional and/or alternative arrangements, the width 117 of trench 118 may range up to a few hundred microns, e.g., 100 μm to 900 μm, depending on implementation.

After removing the substrate via etch mask 112, a refractory metal layer 130A is deposited over the semiconductor device 100 to form a metal liner 131 along the sidewalls 114 and the bottom 119 of the trench 118, where the metal liner 131 may include a bottom 139A that lines the bottom 119 of the trench 118, as shown in FIG. 1C. In some arrangements, the refractory metal layer 130A may be a component of a metal layer stack that may be provided as a first metallization level (e.g., MET1 or M1) of a multilevel interconnect arrangement of the semiconductor device 100. Accordingly, the refractory metal layer 130A may extend over and make contact with the contacts 111 formed with respect to the GaN devices 101 as previously set forth. Depending on implementation, the refractory metal layer may include a refractory metal of at least one of titanium (Ti), tungsten (W), tantalum (Ta), niobium (Nb), cobalt (Co), nickel (Ni), platinum (Pt), molybdenum (Mo), rhenium (Re), vanadium (V), zirconium (Zr), hafnium (Hf), ruthenium (Ru), and iridium (Ir), and/or in combination with a nitride of the refractory metal (e.g., Ti/TiN). In an example implementation, the refractory metal layer 130A may be formed using a sputter process, a reactive sputter process, or an atomic layer deposition (ALD) process, and may have a thickness ranging from about 10 nm to about 40 nm.

FIG. 1D depicts an annealing stage where the bottom 139A of the metal liner 131 is silicided to form a silicide layer 139B operable as a low resistance Ohmic interface with the semiconductor substrate 102. Depending on implementation, rapid thermal annealing (RTA) or furnace annealing may be used where temperatures ranging from about 400° C. to about 800° C. may be applied for suitable time periods. In some examples, an annealing process (e.g., a silicide-forming thermal process) forming the silicide layer 139B in the trench 118 may be configured to form a substrate contact structure having a resistance less than 10 Ω, e.g., ranging from about 0.5 Ω to about 2.5 Ω in some implementations.

In some additional and/or alternative arrangements, an optional implantation step may be provided before depositing the refractory metal layer 130A, where the bottom 119 of the trench 118 may be implanted with one or more species in order to further improve (e.g., reduce) the contact resistance of a substrate contact structure. In versions of this example, the implantation may be done with (1) electrically neutral species (which may damage/disrupt the substrate silicon material to reduce contact resistance), (2) n-type species if the semiconductor substrate 102 is n-type (to locally reduce substrate resistivity, leading to lower contact resistance), and/or (3) p-type species if the semiconductor substrate 102 is p-type (to locally reduce substrate resistivity, leading to lower contact resistance). Further, the optional trench implantation step may be a blanket implant (e.g., without a patterned photoresist) in some arrangements. Accordingly, an example implantation step may include implanting Ar and/or N₂ species into the trench 118 at suitable dosages to damage the substrate silicon material proximate to the bottom 119 of the trench 118. In another variation, an example implantation step may include implanting at least one of arsenic (As) and/or phosphorus (P) where the semiconductor substrate 102 is n-type. In another variation, an example implantation step may include implanting boron (B) where the semiconductor substrate 102 is p-type. In versions of these examples, the semiconductor substrate 102 in contact with the silicide layer 139B may therefore include various implant species depending on implementation.

After forming the silicide layer 139B of the metal liner 131 (with or without optional implantation in the semiconductor substrate 102 contacting the silicide layer 139B), additional metal layers/sublayers of a first metal layer, e.g., metal layer 135, may be deposited over the refractory metal layer 130A as illustrated in FIG. 1E. For example, a conductive layer 130B (e.g., comprising aluminum) and a barrier layer 130C (e.g., comprising a refractory metal layer) may be formed as a substrate contact metal stack operable as the first metal layer 135. Depending on implementation, the conductive layer 130B may have a thickness of about 0.5 μm to 1.0 μm. In some arrangements, the barrier layer 130C may have a thickness ranging from about 10 nm to about 40 nm, and may comprise refractory metals and/or refractory metal nitrides similar to the refractory metal layer 130A.

In some versions, the metal liner 131 may be formed as part of a metal stack of a metallization level (e.g., MET1 including a stack of Ti/TiN/Al/Ti/TiN) of a multilevel interconnect arrangement as previously noted, where the metal liner 131 may comprise a Ti/TiN layer of the metal stack as a refractory layer in an example implementation. After forming the Ti/TiN layer as metal liner 131, a bottom portion of the Ti/TiN layer may be silicided using the silicide-forming thermal process as set forth in FIG. 1D. Thereafter, remaining layers of the metal stack may be deposited, e.g., an aluminum layer (analogous to the conductive layer 130B) formed over the metal liner 131 and a Ti/TiN layer (analogous to the barrier layer 130C) formed over the aluminum layer in an example arrangement. Accordingly, the risk of exposing an aluminum layer of a substrate contact, where aluminum may be desirable, to the silicide-forming thermal process may be eliminated in some examples herein. In this manner, the metal stack may be split to avoid the risk of exposing a metal layer of the metal stack (e.g., aluminum) vulnerable to the thermal budget of the silicide-forming thermal process.

Whereas the silicidation stage set forth in FIG. 1D is illustrative of a scenario where the silicidation takes place immediately after forming the metal liner 131 in the trench 118, some additional and/or alternative arrangements may be configured to provide silicidation using a silicide-forming thermal process after forming the entire substrate contact metal stack. In versions of this example, a conductive layer, e.g., the conductive layer 130B, may be formed to withstand the thermal budget of the silicide-forming thermal process without causing reliability issues. Accordingly, some examples of a substrate contact metal stack of the present disclosure may comprise a conductive layer (or a combination of conductive layers) that may or may not primarily include aluminum. Further, for purposes of the present disclosure, the process of “silicidation” includes “salicidation”, e.g., a self-aligned silicide process where no separate lithographic definition is required.

FIG. 1F depicts a stage after patterning the first metal layer 135 using a metal etch mask and lithography process, where a substrate contact structure 199A including pads 198A and 198B that extend over the third dielectric layer 110 on respective sides of the trench 118 is formed. Further, first level contact pads 197A with respect to the contacts 111 are also formed from the first metal layer 135. Thereafter, interconnect structures at different metal levels may be formed with respect to the substrate contact structure 199A and the contact pads 197A using appropriate metal layers depending on the multilevel metallization arrangement associated with the semiconductor device 100.

As depicted in FIG. 1G, a three-level metallization arrangement including a second level metal layer 137 and a third level metal layer 139 is illustrated by way of example. Different metal layers 135, 137, 139 may be isolated using appropriate inter-level dielectric (ILD) layers and/or inter-metal dielectric (IMD) layers, each comprising one or more sublayers depending on implementation. With respect to the substrate contact structure 199A, the contact pads 198A/198B may be coupled to a second level interconnect structure 199B by way of one or more conductive vias 150A formed in an ILD/IMD layer 175A. In similar fashion, the second level interconnect structure 199B associated with the substrate contact structure 199A may be coupled to a third level interconnect structure 199C using one or more conductive vias 150B formed in an ILD/IMD layer 175B. Likewise, the contact pads 197A associated with the GaN devices 101 may be coupled to respective second level interconnect structures 197B by corresponding conductive vias 151A formed in the ILD/IMD layer 175A. Further, the second level interconnect structures 197B associated with the GaN devices 101 may be coupled to respective third level interconnect structures 197C by corresponding conductive vias 151B formed in the ILD/IMD layer 175B.

In some arrangements, the conductive vias 150A, 150B, 151A and 151B may have a thickness (e.g., width, diameter or a similar horizontal dimension along the X-axis) around 200 nm to 500 nm and a height (e.g., along the Z-axis) around 2 μm or greater. In some implementations, the conductive vias 150A, 150B, 151A and 151B may be formed of copper (Cu) on a barrier liner, formed by a copper damascene process. In some implementations, conductive vias 150A, 150B, 151A and 151B may be formed of aluminum formed in a non-damascene process. A multi-layer protective dielectric structure (which may be referred to as a protective overcoat (PO) structure), e.g., including a PO oxide layer 177A and a PO nitride layer 177B, each having a suitable thickness, is formed over the multilevel metal interconnect arrangement to complete the fabrication of the semiconductor device 100.

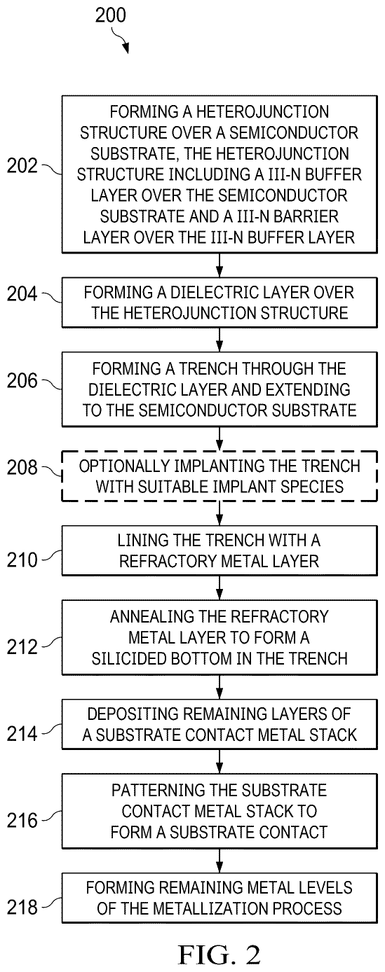

FIG. 2 is a flowchart of a method 200 of fabricating a III-N semiconductor device according to some examples. Method 200 may commence with forming a heterojunction structure over a semiconductor substrate, where the heterojunction structure may include a III-N buffer layer over the semiconductor substrate and a III-N barrier layer over the III-N buffer layer. In some examples, these steps set forth at block 202 may relate to certain aspects of FIG. 1A as described above. At block 204, one or more dielectric layers may be formed over the heterojunction structure, which may relate to additional aspects of FIG. 1A as described above. In some arrangements, the dielectric layer(s) may be planarized using CMP, etch-back process, etc. At block 206, a trench may be formed through the dielectric layer and extending to the semiconductor substrate, which may relate to aspects of FIG. 1B as described above. At block 208, an optional implantation step may be implemented to implant the substrate material exposed in the trench using suitable implant species to reduce contact resistance of a substrate contact to be formed in the trench. At block 210, the trench may be lined with a refractory metal layer. In some examples, the refractory metal layer comprises a combination of a barrier sublayer, an adhesion sublayer and/or anti-reflection sublayer in some arrangements. In some examples, the refractory metal layer includes a part of a metal stack—e.g., Ti/TiN layers of a metal stack of Ti/TiN/Al/Ti/TiN). At least some aspects of block 210 may relate to aspects of FIG. 1C as set forth above.

At block 212, the refractory metal layer may be annealed using a suitable thermal process (e.g., a silicide-forming thermal process) to form a silicided bottom in the trench, which may relate to aspects of FIG. 1D as set forth above. Thereafter, remaining layers/sublayers of a substrate contact metal stack (e.g., Al/Ti/TiN layers of the metal stack of Ti/TiN/Al/Ti/TiN) may be formed based on a metallization process which may include forming metal layers at multiple levels to effectuate a multilevel interconnect arrangement associated with the III-N semiconductor device. These steps set forth in block 214 may relate to aspects of FIG. 1E as described above. At block 216, the metal layers formed as a substrate contact metal stack may be patterned to form a substrate contact where the silicided bottom of the refractory metal layer in the trench is in contact with the semiconductor substrate, which may relate to aspects of FIG. 1F. Thereafter, remaining levels of the metallization process may be implemented with corresponding metal layers to complete the formation of the III-N semiconductor device (block 218) including interconnect structures and inter-level vias, which may relate to aspects of FIG. 1G.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), plasma enhanced CVD (PECVD), or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate;
a heterojunction structure over the semiconductor substrate, the heterojunction structure including a III-N buffer layer over the semiconductor substrate and a III-N barrier layer over the III-N buffer layer; and
a substrate contact extending through the heterojunction structure and to the semiconductor substrate, the substrate contact including a silicide layer.

2. The semiconductor device of claim 1, wherein the silicide layer includes a refractory metal.

3. The semiconductor device of claim 2, wherein the refractory metal includes at least one of titanium, nickel, tungsten, tantalum, niobium, cobalt, platinum, molybdenum, rhenium, vanadium, zirconium, hafnium, ruthenium, and iridium.

4. The semiconductor device of claim 1, further comprising a dielectric layer over the heterojunction structure and the substrate contact is disposed in a trench extending through the dielectric layer.

5. The semiconductor device of claim 1, wherein the silicide layer is in contact with the semiconductor substrate.

6. The semiconductor device of claim 5, wherein the semiconductor substrate in contact with the silicide layer includes an electrically neutral species such as argon or nitrogen.

7. The semiconductor device of claim 5, wherein the semiconductor substrate in contact with the silicide layer is n-type material including at least one of arsenic and phosphorus.

8. The semiconductor device of claim 5, wherein the semiconductor substrate in contact with the silicide layer is p-type material including boron.

9. The semiconductor device of claim 1, wherein the silicide layer has a width ranging from about ≤1 micron (μm) to about 20 μm.

10. A method of fabricating a III-N semiconductor device, comprising:
forming a heterojunction structure over a semiconductor substrate, the heterojunction structure including a III-N buffer layer over the semiconductor substrate and a III-N barrier layer over the III-N buffer layer;
forming a dielectric layer over the heterojunction structure;
forming a trench through the dielectric layer and extending to the semiconductor substrate;
lining the trench with a refractory metal layer; and
annealing the refractory metal layer to form a silicided bottom in the trench.

11. The method of claim 10, wherein the refractory metal layer includes at least one of titanium, nickel, tungsten, tantalum, niobium, cobalt, platinum, molybdenum, rhenium, vanadium, zirconium, hafnium, ruthenium, and iridium.

12. The method of claim 10, further comprising implanting the trench before forming the refractory metal layer.

13. The method of claim 12, wherein the trench is implanted with an electrically neutral species such as argon or nitrogen.

14. The method of claim 12, wherein the trench is implanted with an n-type species such as arsenic or phosphorus.

15. The method of claim 12, wherein the trench is implanted with a p-type species such as boron.

16. The method of claim 10, wherein the silicided bottom has a width ranging from about ≤1 μm to about 20 μm.

17. The method of claim 10, wherein the refractory metal layer has a thickness ranging from about 10 nm to about 40 nm.

18. The method of claim 10, further comprising:
depositing one or more metal layers over the refractory metal layer after annealing.

19. The method of claim 18, wherein the one or more metal layers comprises an aluminum layer.

20. The method of claim 18, further comprising:
etching the one or more metal layers and the refractory metal layer to form a substrate contact of the III-N semiconductor device.
